(19) United States
(12) Patent Application Publication
(10) Pub. No.: US 2003/0029036 A1
(43) Pub. Date: Feb. 13, 2003

(54) Method of repairing a solar panel

(75) Inventor: Reiner Gerson, Elmshorn (DE)

Correspondence Address: CROWELL & MORING LLP, INTELLECTUAL PROPERTY GROUP, P.O. BOX 14300, WASHINGTON, DC, 20044-4300, US

(73) Assignee: Astrium Gmbh, Muenchen (DE)

(21) Appl. No.: 10/214,729

(22) Filed: Aug. 9, 2002

(30) Foreign Application Priority Data
Aug. 10, 2001 (DE) 101 39 441.1

(51) Int. Cl. H01R 43/00; H05K 13/00

(52) U.S. Cl. 29/854; 29/860; 29/876

(57) ABSTRACT

In a method of repairing a solar panel having a defective solar cell array, a solar cell replacement array is glued onto a defective solar cell array of the solar panel and is electrically integrated in the solar panel.

### BACKGROUND AND SUMMARY OF THE INVENTION

This application claims the priority of German patent document 101 30 441.1, filed Aug. 10, 2001, the disclosure of which is expressly incorporated by reference herein.

The invention relates to a method of repairing a solar panel.

Heretofore, the repair of a solar panel with a defective solar cell array has conventionally been implemented by complete removal and replacement of the defective solar cell array, such as described for example, in German patent document DE 1 927 387. Moreover, German patent document DE 2 113 410 describes a repair-friendly arrangement of solar cells in which a defective cell can easily be removed from a module or string of solar cells. Further, German patent document DE 195 39 699 C2 describes a method of utilizing defective solar modules that are of a laminated construction, in which the solar cells are delaminated and the solar module is thereby disassembled into its components. In this state of the art, a relatively high-expenditure intervention into the solar cell array is required in each case.

Such a repair method according to the state of the art may, for example, require the following steps: The cover glass over the solar cell array is removed at the welding islands of the upper “n-connectors” of the solar cell array in order to be able to cut off the (thus exposed) connection webs directly behind the welds and carefully bend them upward. Subsequently, the defective solar cell array must be removed from the solar panel, with the “p-connector” of the array being retained on the panel. A new solar cell array, provided with a special repair connector, is then inserted into the repair point and the projecting n- and p-connectors are welded to the adjacent solar cell arrays. In this high-expenditure technique for removal of the defective solar cell arrays, the panel structure and the adjacent solar cell arrays may be damaged. In addition, special repair connectors are required and a new insulation foil must be glued in.

It is an object of the present invention to provide a simple and safe method for repairing a solar panel having a defective solar cell array.

This and other objects and advantages are achieved by the method according to the invention, in which a defective solar cell array is no longer removed from the panel structure. Rather, a solar cell replacement array is glued onto the defective solar cell array and is electrically integrated in the panel by means of the existing cut-open connectors.

The method according to the invention saves both components and materials. Another important advantage is the saving of repair time because the high-expenditure task of cutting-out of the defective solar cell arrays is eliminated, and only the connectors need be exposed.

A further embodiment of the invention provides that the solar cell replacement array is provided with standard n-connectors and p-connectors which are welded to cut-open connectors of the adjacent intact solar cell arrays.

A silicone bonding agent can be used for the gluing-on of the solar cell replacement array.

The method according to the invention may be performed using a protective cover foil. For this purpose, the solar panel is covered by a Kapton foil, with a window cut out of the Kapton foil over the defective solar cell array. The window edges of the foil are preferably glued by means of adhesive tape onto the adjacent intact solar cell arrays such that the latter arrays are protected by the foil during the repair operation. This process step is therefore advisable when a special protection of the adjacent solar cell arrays is to be ensured.

Other objects, advantages and novel features of the present invention will become apparent from the following detailed description of the invention when considered in conjunction with the accompanying drawings.

### BRIEF DESCRIPTION OF THE DRAWINGS

FIG. 1 is a broken away view of a solar panel having a defective solar cell array;

FIG. 2 is a broken away sectional view of the solar panel in FIG. 1, with a solar cell replacement array prepared for the priming; and

FIG. 3 is a broken away view of the solar panel of FIG. 1, with the inserted solar cell replacement array.

### DETAILED DESCRIPTION OF THE INVENTION

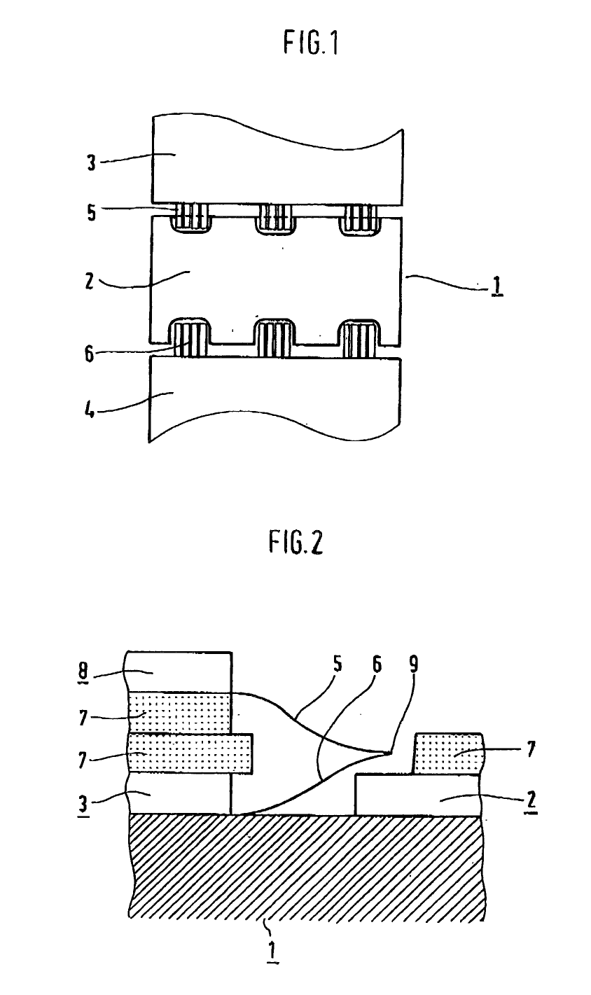

The broken away portion of a solar panel 1 illustrated in FIG. 1 shows a defective solar cell array 2 and its electrical integration between two adjacent intact solar cell arrays 3 and 4. The electrical series connection of the arrays with respect to one another takes place in a known manner by means of n-connectors 5 and p-connectors 6, several connectors being combined in each case in a welding island. (In the illustrated embodiment, there are four n- or p-connectors respectively for each welding island.) Each of the solar cell arrays illustrated in FIG. 1, for example, has three welding islands for the n- and p-connectors.

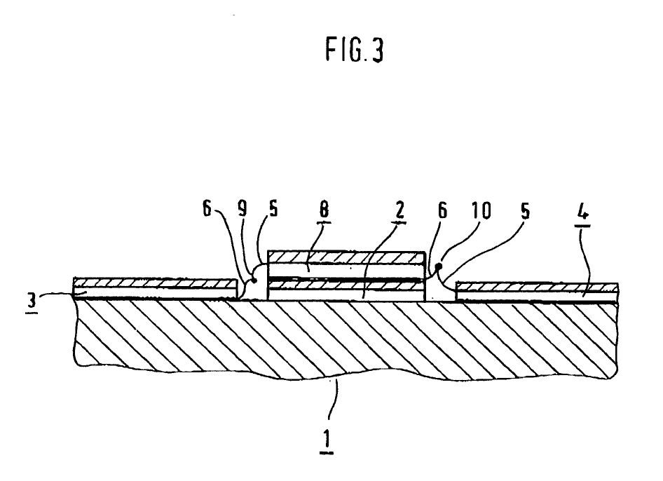

For implementing the method according to the invention, the solar panel 1 is first covered by means of a Kapton foil which is cut out over the defective solar cell array 2. The window edges of the Kapton foil are glued onto the adjacent intact solar cell arrays by means of adhesive tape. Subsequently, the n- and p-connectors are exposed on the defective solar cell array 2. For this purpose, the cover glass 7 over the welding islands of the n-connectors 5 is partially removed and, on the welding islands of the p-connectors 6, the defective solar cell array 2 is partially removed starting from its cover glass 7 down to the p-connectors 6 in the area of the welding islands. (See FIGS. 2, 3.) The webs of the exposed n- and p-connectors 5 and 6 are then cut and bent upward.

At the thus prepared repair point, the solar cell replacement array 8, with its cover glass 7 first, is next deposited (upside down as shown in FIG. 2) onto the cover glass 7 of one of the adjacent intact solar cell arrays 3 or 4, and is temporarily fixed there by means of an adhesive tape.

The solar cell replacement array 8 is equipped with standard-type n- and p-connectors. The n-connectors 5 (for example) of the solar cell replacement array 8 are connected with the p-connectors 6 of the intact solar cell array (in FIG. 2, for example, the intact solar cell array 3) by means of a spot weld 9.

Then, the p-side of the solar cell replacement array 8 and the surface of the cover glass 7 of the defective solar cell arrangement 2 are primed and, after evaporation of the applied primer, a bonding agent is applied to the primed surface of the defective solar cell array. The bonding agent may, for example, be a silicone bonding agent, such as a silicone rubber. A special example of such a silicone rubber is product “RTV-S691” of Wacker Company.

FIG. 3 illustrates the subsequent end phase of the repair operation. The solar cell replacement array 8 is folded over and is placed with its p-side onto the defective solar cell array 2 and is aligned there. After the hardening of the bonding agent, the p-connectors 6 of the solar cell replacement array 8 are connected with the n-connectors 5 of the other intact solar cell array by way of a welding spot 10.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A method of repairing a solar panel comprising a plurality of mutually electrically connected solar cell arrays, said method comprising:
gluing a solar cell replacement array onto a defective solar cell array of the solar panel; and
electrically connecting the glued on replacement array to the solar panel.

2. The method according to claim 1, wherein
the solar cell replacement array includes standard n-connectors and p-connectors; and
said electrically connecting comprises welding the n- and p-connectors of the replacement array to cut-open connectors of an adjacent intact solar cell arrays.

3. The method according to claim 1, wherein silicone bonding agent is used for gluing on the solar cell replacement array.

4. The method according to claim 1, wherein a protective cover foil is first applied to solar cell arrays adjoining the defective solar cell array.

5. A method for repairing a solar panel comprising a matrix of individual solar cell arrays, each having a plurality of n-connectors and p-connectors and being covered by a layer of cover glass, said method comprising:
removing the cover glass and a portion of a defective solar cell array adjacent welding islands of the n- and p-connectors;
gluing a replacement solar cell array onto the defective solar cell array; and
electrically connecting the connectors of the replacement solar cell array to connectors of adjacent solar cell arrays.

6. A method for repairing a solar panel comprising a matrix of individual solar cell arrays, each having a plurality of n-connectors and p-connectors and being covered by a layer of cover glass, said method comprising:
removing the cover glass and a portion of a defective solar cell array adjacent welding islands of the n- and p-connectors;
cutting the connectors and bending them upwards;
placing a replacement solar cell array upside down adjacent the defective solar cell array;
connecting the n- or p-type connectors on the replacement solar cell array to connectors on a first solar cell array adjacent the defective solar cell array;
folding the replacement solar cell array over and bonding it to unremoved glass covering the defective solar cell array; and
connecting remaining connectors of said replacement solar cell array to connectors of a second solar cell array adjacent defective solar cell array.
